(19) United States
(12) Patent Application Publication
(10) Pub. No.: US 2011/0011631 A1
(43) Pub. Date: Jan. 20, 2011

(54) Ceramic substrate and method of manufacturing the same

(75) Inventors: Won Hee YOO, Suwon-si (KR); Byeung Gyu CHANG, Suwon-si (KR); Yong Suk KIM, Yongin-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO.,, Suwon (KR)

(21) Appl. No.: 12/585,006

(22) Filed: Aug. 31, 2009

(30) Foreign Application Priority Data
Jul. 16, 2009 (KR) 10-2009-0064962

(51) Int. Cl. H05K 1/09; B05D 5/12; H05K 1/03

(52) U.S. Cl. 174/257; 427/58; 174/258

(57) ABSTRACT

The present invention relates to a ceramic substrate and a method of manufacturing the same. The ceramic substrate includes: a ceramic base; an electrode pattern formed on at least one surface of the ceramic base at predetermined internal and external depths; and electrode material filled in the inside of the electrode pattern. The method of manufacturing the ceramic substrate includes: coating first electrode material on at least one surface of a ceramic base; forming a surface layer built-in electrode pattern by pressurizing the coated first electrode material; primarily firing the ceramic base on which the surface layer built-in electrode pattern is formed; coating second electrode material on the surface layer built-in electrode pattern; and secondarily firing the ceramic base on which the second electrode material is coated.

### CROSS-REFERENCE TO RELATED APPLICATIONS

The present application claims priority under 35 U.S.C. 119 and 35 U.S.C. 365 to Korean Patent Application No. 10-2009-0064962 (filed on Jul. 16, 2009), which is hereby incorporated by reference in its entirety.

### BACKGROUND OF THE INVENTION

1. Field of the Invention

The present invention relates to a ceramic substrate and a method of manufacturing the same, and more particularly, to a ceramic substrate that forms an external substrate through processes of secondarily forming an electrode pattern on the same position and secondarily firing a ceramic substrate on which the electrode pattern is formed to improve adhesive strength between the electrode and the ceramic substrate by physical/chemical couplings, and a method of manufacturing the same.

2. Description of the Related Art

With the reinforcement and maintenance of the recent miniaturization trend in electronic component fields, miniaturized modules and substrates through precision, fine patterning and thinning of the electronic components have been developed. However, when a commonly used printed circuit board (PCB) is used in a miniaturized electronic component, disadvantages arise in view of miniaturization in size, signal loss in a high frequency region, and degradation of reliability at the time of high temperature and high humidity.

In order to overcome such disadvantages, a ceramic substrate is used. The main component of the ceramic substrate is ceramic composition including a great quantity of glass that can be low temperature co-fired.

The low temperature co-fired ceramic (LTCC) technology that is commonly used as a multi-layer structure is a technology to form a substrate using a co-firing method of ceramic and metal at a relatively low temperature of 800° C. to 1000° C.

The LTCC substrate forms a green sheet having proper dielectric constant by mixing glass with low meting point with ceramic, prints a conductive paste thereon to print passive devices such as a capacitor, a register or an inductor, in patterns, and then stacks the respective sheets, thereby forming a substrate.

The ceramic substrate may be manufactured by forming a laminate wherein an internal electrode and a via for connecting patterns of the respective interlayers are formed and stacked on the ceramic green sheet formed in a sheet shape by mixing binder and other additives with the ceramic, and forming and firing an external electrode for an electrical connection with an external substrate or a component on the surface thereof. Alternately, the ceramic substrate may be obtained by forming and firing the internal electrode and the conductive via on the ceramic green sheet, and then separately forming the external electrode and secondarily firing the fired internal electrode.

After printing a solder paste in order to mount external devices, devices such as a high-capacity chip capacitor, a chip inductor, a chip resistor, and a surface acoustic wave (SAW) filter are mounted on the surface of the LTCC substrate, thereby inducing function complexity.

However, it comes to a limitation in the number of devices and the areas thereof that can be mounted on the substrate according to the recent miniaturization trend of the LTCC module. Problems arises in that a defect that an undesired electrical conduction between the mounted components is generated by the spread of the solder paste for adhesion when the devices are mounted on the surface due to the reduction of the intervals between the devices and the built-in device is affected by the humidity of the outside through the via inside the LTCC substrate.

FIG. 1 is a flowchart illustrating a method of manufacturing a ceramic substrate in the related art.

As shown in FIG. 1, the method of manufacturing the ceramic substrate in the related art includes: providing a fired ceramic substrate 11; printing an external electrode on a surface layer part of the fired ceramic substrate 12; and firing the ceramic substrate on which the external electrode is formed 13.

In other words, the method of manufacturing the ceramic substrate in the related art forms the external electrode of the ceramic substrate through the processes of printing the electrode on the surface layer part of the fired ceramic substrate and then firing again the ceramic substrate on which the electrode is formed.

The method as described above is subject to processes of printing 12 the electrode on the fired ceramic substrate 11 at a temperature of about 850° C. and then secondarily firing it again at a temperature of about 800° C. However, the ceramic substrate and the external electrode are fired at different temperatures, having a limitation in improving adhesive strength.

In particular, the improvement in the adhesive strength of the external electrode of the ceramic substrate is an indispensable requirement in improving the reliability of SMT process and packaging process, having a difficulty in applying the packaging condition requiring a high reliability.

### SUMMARY OF THE INVENTION

The present invention relates to a ceramic substrate that forms an external substrate through processes of secondarily forming an electrode pattern on the same position and secondarily firing a ceramic substrate on which the electrode pattern is formed to improve adhesive strength between the electrode and the ceramic substrate by physical/chemical couplings, and a method of manufacturing the same.

There is provided a ceramic substrate including: a ceramic base, an electrode pattern formed on at least one surface of the ceramic base at predetermined internal and external depths; and electrode material filled in the inside of the electrode pattern.

Preferably, the ceramic base of the ceramic substrate according to the present invention includes at least one of SiO₂, MgO, CaCO₃, and alumina, and the electrode material includes at least one of Ag, Ni, Au, and Cu.

Preferably, the electrode pattern of the ceramic substrate according to the present invention is formed at a thickness of 1 to 4 μm.

There is provided a method of manufacturing a ceramic substrate including: coating first electrode material on at least one surface of a ceramic base; forming a surface layer built-in electrode pattern by pressurizing the coated first electrode material; primarily firing the ceramic base on which the surface layer built-in electrode pattern is formed; coating second electrode material on the surface layer built-in electrode pattern; and secondarily firing the ceramic base on which the second electrode material is coated.

Preferably, in the coating the second electrode material on the surface layer built-in electrode pattern of the method of manufacturing the ceramic substrate according to the present invention, the surface layer built-in electrode pattern matches with the pattern that the second electrode material is coated one to one or the pattern that the second electrode material is coated is formed to be larger than the surface layer built-in electrode pattern.

Preferably, the ceramic base of the method of manufacturing the ceramic substrate according to the present invention includes at least one of SiO₂, MgO, CaCO₃, and alumina, and the first or second electrode material includes at least one of Ag, Ni, Au, and Cu.

Preferably, the first electrode material and the second electrode material of the method of manufacturing the ceramic substrate according to the present invention are made of the same material.

Preferably, the firing temperature of the primary firing process of the method of manufacturing the ceramic substrate according to the present invention is below 500° C. and the firing temperature of the secondary firing process is 500° C. or more.

Preferably, in the primary firing process and the secondary firing process of the method of manufacturing the ceramic substrate according to the present invention, chemical couplings are made between the ceramic base and the first electrode material and between the first electrode material and the second electrode material.

### BRIEF DESCRIPTION OF THE DRAWINGS

FIG. 1 is a flowchart illustrating a method of manufacturing a ceramic substrate in the related art;

FIG. 2 is a flowchart illustrating a method of manufacturing a ceramic substrate according to an embodiment of the present invention;

FIG. 3 illustrates adhesive strength experimental data between the ceramic substrate in the related art and the external electrode of the ceramic substrate according to the embodiment of the present invention; and

FIGS. 4A and 4B are diagrams illustrating breakdown forms of the adhesive strength between the ceramic substrate in the related art and the external electrode of the ceramic substrate according to the embodiment of the present invention.

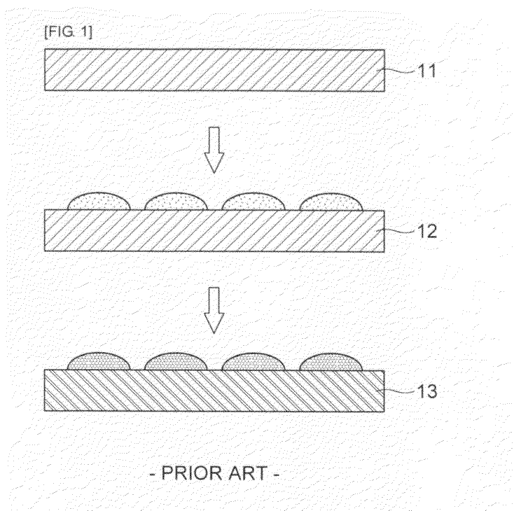

### DETAILED DESCRIPTION OF THE PREFERRED EMBODIMENTS

The present invention will now be described more fully hereinafter with reference to the accompanying drawings, in which exemplary embodiments of the invention are illustrated.

The present invention may, however, be embodied in different forms and should not be construed as limited to the embodiments set forth herein. Rather, the present invention is intended to cover various modifications and equivalent arrangements included within the spirit and scope of the appended claims, and equivalent thereof.

Hereinafter, a ceramic substrate and a method of manufacturing the same according to an embodiment of the present invention will be described in detail with reference to the accompanying drawings, and the same or corresponding constituents irrespective of drawing reference numerals will be given with the same reference numerals and the overlapped explanation thereof will be omitted.

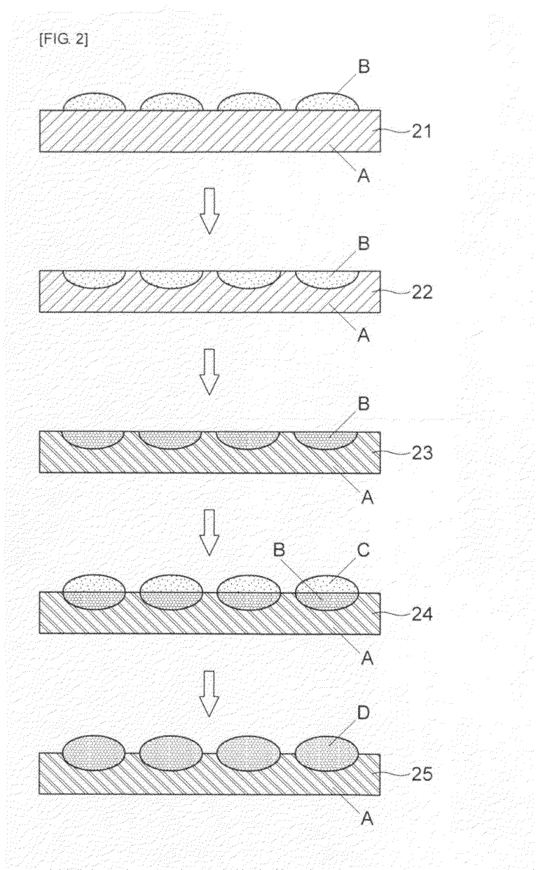

FIG. 2 is a flowchart illustrating a method of manufacturing a ceramic substrate according to an embodiment of the present invention.

As shown in FIG. 2, the method of manufacturing the ceramic substrate according to the embodiment of the present invention includes: coating first electrode material on one surface of a ceramic base 21; forming a surface layer built-in electrode pattern by pressurizing the coated first electrode material 22; primarily firing the ceramic base on which the surface layer built-in electrode pattern is formed 23; coating second electrode material on the surface layer built-in electrode pattern 24; and secondarily firing the ceramic base coated with the second electrode material 25.

The coating the first electrode material B on at least one surface of the ceramic base A 21 comprises coating the first electrode material B in a land pattern on the surface layer part of the ceramic base A at a thickness of approximately 1 to 2 μm.

The ceramic base A may include at least one of SiO₂, MgO, CaCO₃ and alumina, and the first electrode material B may be made of at least one material of Ag, Ni, Au, and Cu or a compound thereof.

In the forming the surface layer built-in electrode pattern B of the ceramic base A by pressurizing the coated first electrode material B 22, the ceramic base A is in a state that it is not fired, such that the surface layer built-in electrode pattern B of the ceramic base A may be formed by physically applying pressure using a press equipment, etc.

If the surface layer built-in electrode pattern is formed, the ceramic base A on which the surface layer built-in electrode pattern B is formed is primarily fired 23, and the ceramic base A on which the surface'layer built-in electrode pattern B is formed after the firing is solidified in a predetermined shape.

After completing the primary firing, the second electrode material C is coated on the surface layer built-in electrode pattern B 24 and the ceramic base A coated with the second electrode material C is secondarily fired 25, thereby making it possible to manufacture the ceramic substrate.

The second electrode material C may include at least one material of Ag, Ni, Au, and Cu, or a compound thereof, wherein the second electrode material C is preferably made of the same material as the first electrode material B.

In the process 24 of coating the second electrode material C on the surface layer built-in electrode pattern B, the surface layer built-in electrode pattern B may match with the pattern that the second electrode material C is coated one to one or the pattern that the second electrode material C is coated may be formed to be larger than the surface layer built-in electrode pattern B.

Further, the radius of the pattern that the second electrode material C is coated may be formed in the size of 100 to 150 μm, wherein the formed electrode pattern is preferably formed at a thickness of 1 to 4 μm.

Generally, the firing temperature of the primary firing process is below 500° C. and the firing temperature of the secondary firing process is 500° C. or more, such that the first electrode material B and the second electrode material C may be chemically coupled.

In other words, a physical coupling is generated during the process of pressurizing the first electrode material, a primary chemical coupling is generated from a contact surface between the first electrode material B and the ceramic base A by the primary firing process, and a secondary chemical coupling is generated from between the second electrode material C and the first electrode material B and between the first electrode material B and the ceramic base A, respectively, by the secondary firing process.

Therefore, the external electrode pattern D completing the secondary firing has an improved adhesive strength by the physical and chemical couplings.

Compared with the method of forming the external electrode on the surface layer of the fired ceramic base, the method of manufacturing the ceramic substrate according to the embodiment of the present invention greatly increases the respective chemical couplings between the ceramic base and the first electrode material and between the first electrode material and the second electrode material, thereby making it possible to improve the adhesive strength.

The ceramic substrate according to the embodiment of the present invention includes a ceramic base, an electrode pattern formed on at least one surface of the ceramic base at predetermined internal and external depths, and electrode material filled in the inside of the electrode pattern.

The ceramic base may be made of material including at least one of SiO₂, MgO, CaCO₃, and alumina or a compound thereof, and the electrode material may be made of material including at least one of Ag, Ni, Au, and Cu or a compound thereof.

The ceramic substrate and the electrode material filled in the inside of the electrode pattern may be applied with a primary firing process below 500° C. and a secondary firing process of 500° C. or more.

The electrode pattern may be formed at a thickness of 1 to 4 μm, the radius of the electrode pattern may be formed at 100 to 150 μm, and the electrode pattern may be formed in a land pattern.

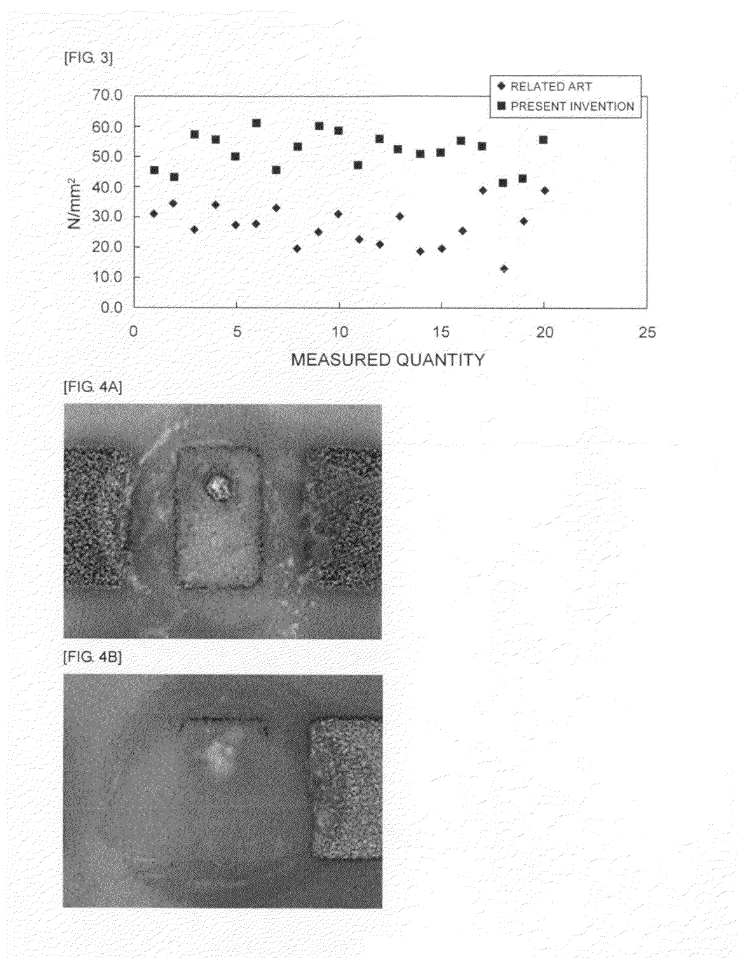

FIG. 3 illustrates adhesive strength experimental data between the ceramic substrate in the related art and the external electrode of the ceramic substrate according to the embodiment of the present invention, and FIG. 4 is a diagram illustrating breakdown forms of the adhesive strength between the ceramic substrate in the related art and the external electrode of the ceramic substrate according to the embodiment of the present invention.

As shown in FIG. 3, the adhesive strength may be represented by force required in breaking down the external electrode per unit area.

The average of the adhesive strength of the ceramic substrate in the related art is 27.3 N/mm², and the minimum adhesive strength and the maximum adhesive strength thereof are 12.9 N/mm² and 38.8 N/mm², respectively. Meanwhile, the average of the adhesive strength of the ceramic substrate according to the embodiment of the present invention is 51.7 N/mm², and the minimum adhesive strength and the maximum adhesive strength thereof are 41.3 N/mm² and 60.9 N/mm², respectively.

Compared with the adhesive strength of the ceramic substrate in the related art, it can be appreciated that the average of the adhesive strength of the embodiment of the present invention is improved by about twice, and the minimum adhesive strength and the maximum adhesive strength thereof are improved by about 1.5 to 3 times, respectively.

As shown in FIG. 4, when comparing the breaking down forms of the adhesive strength between the ceramic substrate in the related art and the external electrode of the ceramic substrate according to the embodiment of the present invention, only a portion of the electrode pattern is broken down (a) in the ceramic substrate in the related art, whereas the entirety of the electrode pattern is broken down (b) in the ceramic substrate according to the embodiment of the present invention.

In order to break down the external electrode of the ceramic substrate according to the embodiment of the present invention, greater force is required compared to the case where the external electrode of the ceramic substrate in the related art is broken down. This means that the adhesive strength of the external electrode of the ceramic substrate according to the embodiment of the present invention is improved by 1.5 times or more compared to the adhesive strength of the external electrode of the ceramic substrate in the related art.

With the embodiment of the present invention, the physical and chemical couplings are made between the electrode and the ceramic base through the secondary electrode pattern forming process and the secondary firing process to overcome the limitation in the adhesive strength of the external electrode of the ceramic substrate in the related art, making it possible to improve the adhesive strength of the external electrode of the surface layer part of the ceramic substrate.

In addition, the patterns in various shapes such as a circular pattern, a rectangular pattern, etc. can be applied to the surface layer part of the ceramic substrate, and the stability in the high reliability packaging process can be secured.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A ceramic substrate comprising:
a ceramic base;
an electrode pattern formed on at least one surface of the ceramic base at predetermined internal and external depths; and
electrode material filled in the inside of the electrode pattern.

2. The ceramic substrate according to claim 1, wherein the ceramic base includes at least one of SiO₂, MgO, CaCO₃, and alumina, and the electrode material includes at least one of Ag, Ni, Au, and Cu.

3. The ceramic substrate according to claim 1, wherein the thickness of the formed electrode pattern is 1 to 4 μm.

4. A method of manufacturing a ceramic substrate, comprising:
coating first electrode material on at least one surface of a ceramic base;
forming a surface layer built-in electrode pattern by pressurizing the coated first electrode material;
primarily firing the ceramic base on which the surface layer built-in electrode pattern is formed;
coating second electrode material on the surface layer built-in electrode pattern; and
secondarily firing the ceramic base on which the second electrode material is coated.

5. The method of manufacturing the ceramic substrate according to claim 4, wherein in the coating the second electrode material on the surface layer built-in electrode pattern, the surface layer built-in electrode pattern matches with the pattern that the second electrode material is coated one to one or the pattern that the second electrode material is coated is formed to be larger than the surface layer built-in electrode pattern.

6. The method of manufacturing the ceramic substrate according to claim 4, wherein the ceramic base includes at least one of SiO₂, MgO, CaCO₃, and alumina, and the first or second electrode material includes at least one of Ag, Ni, Au, and Cu.

7. The method of manufacturing the ceramic substrate according to claim 4, wherein the first electrode material and the second electrode material are made of the same material.

8. The method of manufacturing the ceramic substrate according to claim 4, wherein the firing temperature of the primary firing process is below 500° C. and the firing temperature of the secondary firing process is 500° C. or more.

9. The method of manufacturing the ceramic substrate according to claim 4, wherein in the primary firing process and the secondary firing process, chemical couplings are made between the ceramic base and the first electrode material and between the first electrode material and the second electrode material.
